(19) United States
(12) Patent Application Publication
(10) Pub. No.: US 2025/0351351 A1
(43) Pub. Date: Nov. 13, 2025

(54) SEMICONDUCTOR MEMORY DEVICE

(71) Applicant: Samsung Electronics Co., Ltd., Suwon-si (KR)

(72) Inventors: Jaeryong SIM, Suwon-si (KR); Kohji KANAMORI, Suwon-si (KR); Sejie TAKAKI, Suwon-si (KR); Jeehoon HAN, Suwon-si (KR)

(73) Assignee: Samsung Electronics Co., Ltd., Suwon-si (KR)

(21) Appl. No.: 18/937,644

(22) Filed: Nov. 5, 2024

(30) Foreign Application Priority Data
May 9, 2024 (KR) 10-2024-0061427

(51) Int. Cl. H10B 43/27; H10B 43/10; H10B 43/35; H10B 43/40

(52) U.S. Cl. CPC H10B 43/27; H10B 43/10; H10B 43/35; H10B 43/40

(57) ABSTRACT

A semiconductor memory device according to some example embodiments may include a source plate including a semiconductor material, a mold structure on a bottom surface of the source plate, the mold structure including a plurality of gate electrodes and a plurality of mold insulating layers alternately stacked on each other in a first direction, the first direction being perpendicular to the bottom surface of the source plate, each of the plurality of gate electrodes and the plurality of mold insulating layers extend in a second direction, the second direction being parallel to the bottom surface of the source plate, a plurality of channel structures penetrating the mold structure in the first direction, and each of the plurality of channel structures including a channel hole extending in the first direction, a charge storage structure on an inner wall of the channel hole, and a channel layer on the charge storage structure.

### CROSS-REFERENCE TO RELATED APPLICATION

This application claims priority to Korean Patent Application No. 10-2024-0061427, filed in the Korean Intellectual Property Office on May 9, 2024, the entire contents of which are hereby incorporated by reference.

### BACKGROUND

Various example embodiments relate to a semiconductor memory device.

There is an increasing need for semiconductor memory devices capable of storing high-capacity data in an electronic systems that requires data storage. Accordingly, ways to increase the data storage capacity of semiconductor memory devices are being studied. For example, methods for increasing the data storage capacity of the semiconductor device have been proposed, which includes examples of three-dimensional arrangements of memory cells instead of the conventional two-dimensional arrangements.

### SUMMARY

In order to solve one or more problems (e.g., the problems described above and/or other problems not explicitly described herein), various example embodiments provide a semiconductor memory device.

A semiconductor memory device according to some example embodiments may include a source plate including a semiconductor material, a mold structure on a bottom surface of the source plate, the mold structure including a plurality of gate electrodes and a plurality of mold insulating layers alternately stacked on each other in a first direction, the first direction being perpendicular to the bottom surface of the source plate, each of the plurality of gate electrodes and the plurality of mold insulating layers extend in a second direction, the second direction being parallel to the bottom surface of the source plate, a plurality of channel structures penetrating the mold structure in the first direction, and each of the plurality of channel structures including a channel hole extending in the first direction, a charge storage structure on an inner wall of the channel hole, and a channel layer on the charge storage structure. The source plate includes a first conductivity type impurity region and a second conductivity type impurity region, and the channel layer extends along the bottom surface of the source plate in the second direction.

A semiconductor memory device according to some example embodiments may include a peripheral circuit structure, a first cell structure on the peripheral circuit structure, the peripheral circuit structure including a peripheral circuit substrate, a plurality of circuit elements on the peripheral circuit substrate, a metal layer connected to each of the plurality of circuit elements, and an interlayer insulating layer on the peripheral circuit substrate to bury the plurality of circuit elements and the metal layer, the first cell structure including a first source plate, the first source plate including a semiconductor material, a first conductivity type impurity region, and a second conductivity type impurity region, a first mold structure including a plurality of gate electrodes and a plurality of mold insulating layers on a bottom surface of the first source plate and alternately stacked on each other in a first direction perpendicular to the bottom surface of the first source plate, each of the plurality of gate electrodes and the plurality of mold insulating layers extending in a second direction parallel to the bottom surface, a plurality of first channel structures penetrating the first mold structure in the first direction, each of the plurality of first channel structures including a channel hole extending in the first direction, a charge storage structure on an inner wall of the channel hole, and a channel layer on the charge storage structure, a first bit line under the plurality of first channel structures, and the channel layer extending along the bottom surface of the first source plate in the second direction.

According to some example embodiments, a semiconductor memory device may include a source plate including a semiconductor material, the source plate including a first conductivity type impurity region and a second conductivity type impurity region, a mold structure on a bottom surface of the source plate, the mold structure including a plurality of gate electrodes and a plurality of mold insulating layers alternately stacked on each other in a first direction perpendicular to the bottom surface of the source plate, each of the plurality of gate electrodes and the plurality of mold insulating layers extending in a direction parallel to the bottom surface of the source plate, a plurality of channel structures penetrating the mold structure in the first direction, each of the plurality of channel structures including a channel hole extending in the first direction, a charge storage structure on an inner wall of the channel hole, a channel layer on the charge storage structure, and the channel layer being in contact with the source plate, a block separation structure penetrating the mold structure in the first direction, the first conductivity type impurity region on the block separation structure, a bit line under the plurality of channel structures, the channel layer extending along the bottom surface of the source plate in a second direction, the second direction being perpendicular from the first direction, and the channel layer including a channel array region including the plurality of channel structures arranged along second and third directions perpendicular to the first direction, the second and third directions being perpendicular to each other, and a block separation region including the block separation structure extending in the second direction and separating the channel array region into a plurality of blocks. The block separation structure includes a plurality of block separation structures spaced apart in the third direction.

According to some example embodiments of the present disclosure, in an erase operation, it is possible to apply the erase voltage through the impurity region formed on the source plate disposed above the channel hole, so that a sufficient amount of erase voltage can be applied to the channel layer of the channel structure without requiring a separate complex structure (e.g., GIDL WL) for the erase operation.

Furthermore, according to various example embodiments, the first conductivity type impurity region for program operation and the second conductivity type impurity region for erase operation are separately formed on the source plate (SP), thereby reducing or minimizing interference between a moving path of electric charges in the program operation and a moving path of electric charges in the erase operation, and providing a semiconductor memory device with improved reliability and/or stability.

Various beneficial advantages and effects of the present disclosure are not limited to those described above, and can be more easily understood in the course of describing specific aspects of the present disclosure.

### BRIEF DESCRIPTION OF THE DRAWINGS

The above objects, features, and advantages of the present disclosure will become more apparent to those of ordinary skill in the art by describing in detail various example embodiments thereof with reference to the accompanying drawings, in which:

FIG. 1 is a circuit diagram conceptually illustrating a memory array region of a semiconductor device according to various example embodiments;

FIG. 2 is an example layout diagram provided to explain a semiconductor memory device according to various example embodiments;

FIG. 3 is a cross-sectional view taken along the cross section A-A of FIG. 2;

FIG. 4 is an enlarged diagram provided to explain a semiconductor memory device with respect to the region EX2 of FIG. 3;

FIG. 5 is an enlarged diagram provided to explain a semiconductor memory device according to various example embodiments with respect to the region EX2 of FIG. 3;

FIG. 6 is a plan view of a source plate with respect to the region EX1 of FIG. 2;

FIG. 7 is a cross-sectional view taken along the cross section B-B of FIG. 6;

FIG. 8 is a cross-sectional view taken along the cross section C-C of FIG. 6;

FIG. 9 is a plan view of a source plate according to various example embodiments with respect to the region EX1 of FIG. 2;

FIG. 10 is a cross-sectional view taken along the cross section D-D of FIG. 9;

FIG. 11 is a plan view of a source plate according to various example embodiments with respect to the region EX1 of FIG. 2;

FIG. 12 is a cross-sectional view taken along the cross section E-E of FIG. 11;

FIGS. 13 to 24 are diagrams provided to explain a method of manufacturing a semiconductor device according to various example embodiments, which illustrate intermediate stages of manufacturing.

FIG. 25 is a diagram provided to explain a semiconductor memory device according to various example embodiments;

FIG. 26 is a conceptual diagram schematically illustrating an electronic system including a semiconductor memory device according to various example embodiments; and

FIG. 27 is a perspective view schematically illustrating an electronic system including a 3D semiconductor memory device according to various example embodiments.

### DETAILED DESCRIPTION

Hereinafter, various example embodiments will be described as follows with reference to the accompanying drawings.

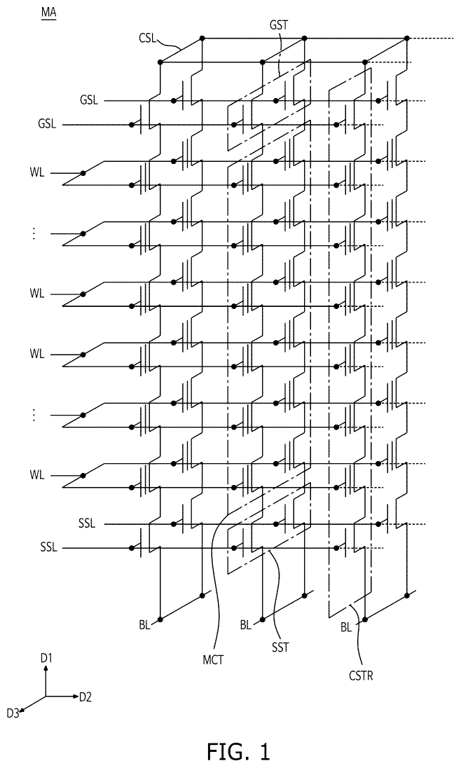

FIG. 1 is a circuit diagram conceptually illustrating a memory array region MA of a semiconductor device.

Referring to FIG. 1, a memory array of the semiconductor device may include a common source line CSL, a plurality of bit lines BL, and a plurality of cell strings CSTR disposed between the common source line CSL and the plurality of bit lines BL. The common source line CSL, the plurality of cell strings CSTR, and the plurality of bit lines BL may be arranged along a first direction D1.

The common source line CSL may extend in a second direction D2 perpendicular to the first direction. In some example embodiments, the plurality of common source lines CSL may be arranged two-dimensionally. For example, the plurality of common source lines CSL may be spaced apart from each other and may extend in the second direction D2, respectively. The same voltage may be applied to the common source line CSL, or different voltages may be applied to be separately controlled.

The plurality of bit lines BL may be arranged two-dimensionally. For example, the plurality of bit lines BL may be spaced apart from each other and may extend in a third direction D3 intersecting the second direction D2. Each of the bit lines BL may be connected in parallel with the plurality of cell strings CSTR.

The plurality of cell strings CSTR may be coupled in common to the common source line CSL. The plurality of cell strings CSTR may be disposed between the common source line CSL and the plurality of bit lines BL. Each of the plurality of cell strings CSTR may include a ground select transistor GST, memory cell transistors MCT, and a string select transistor SST. The ground select transistor GST, the memory cell transistors MCT, and the string select transistor SST may be connected to each other in series.

The memory cell transistors MCT may be connected to each other in series between the ground select transistor GST and the string select transistor SST. Each of the memory cell transistors MCT may include information storage regions capable of storing information. For example, each of the memory cell transistors MCT may include a data storage element.

There may be a plurality of ground select transistors GST which may be electrically connected to the common source line CSL. There may be a plurality of string transistors SST which may be electrically connected to the bit line BL.

A ground select line GSL, a plurality of word lines WL, and a string select line SSL may be disposed between the common source line CSL and the bit lines BL. The ground select transistor GST may be controlled by the ground select line GSL. For example, the ground select line GSL may be used as a gate electrode of the ground select transistor GST. The common source line CSL may be connected in common to a source of the ground select transistor GST. The string select transistor SST may be controlled by the string select line SSL. The memory cell transistors MCT may be controlled by a plurality of word lines WL. For example, the string select line SSL may be used as a gate electrode of the string select transistor SST, and a plurality of word lines WL may be used as gate electrodes of the memory cell transistors MCT.

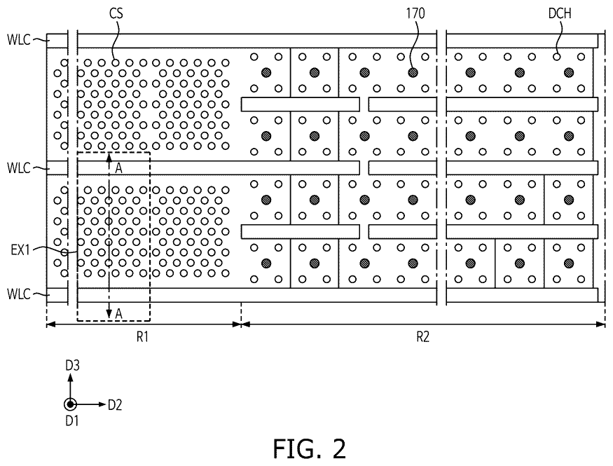

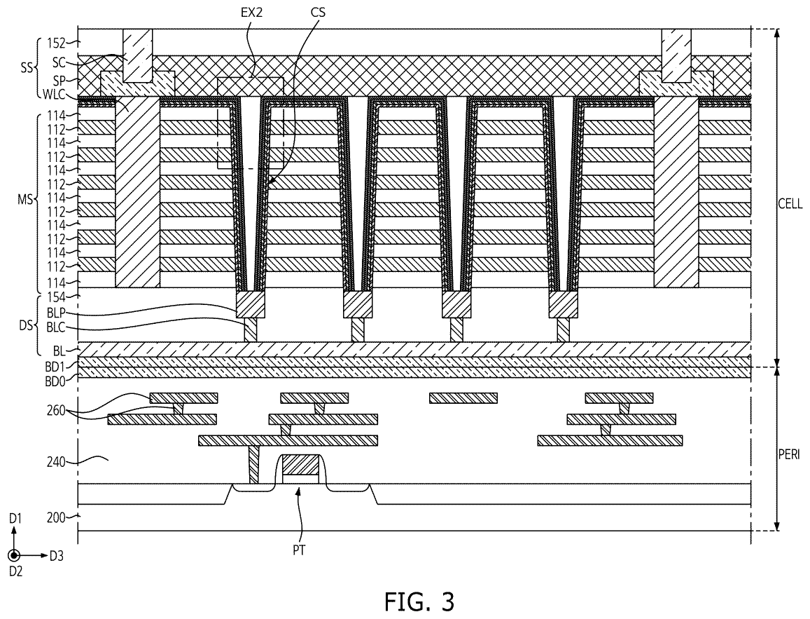

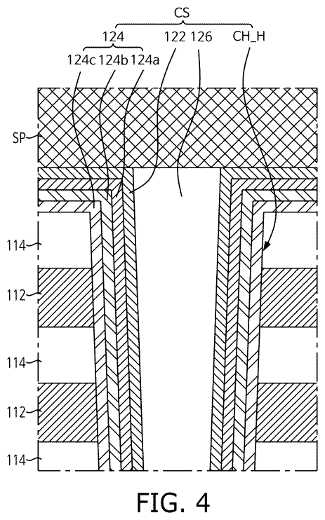

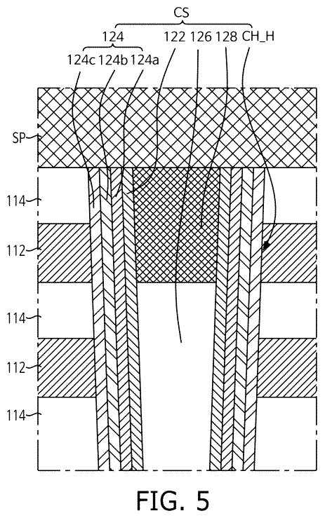

FIG. 2 is an example layout diagram provided to explain a semiconductor memory device. FIG. 3 is a cross-sectional view taken along the cross section A-A of FIG. 2. FIG. 4 is an enlarged diagram provided to explain a semiconductor memory device with respect to the region EX2 of FIG. 3. FIG. 5 is an enlarged diagram provided to explain a semiconductor memory device according to various example embodiments with respect to the region EX2 of FIG. 3.

Referring to FIGS. 2 to 5, a semiconductor memory device according to some example embodiments may include a memory cell region CELL and a peripheral circuit region PERI.

The memory cell region CELL may include a cell array region R1 and an extended region R2. A memory cell array (e.g., MA of FIG. 1) including a plurality of memory cells may be formed in the cell array region R1. For example, a channel structure CS, a bit line BL, a gate electrode 112, etc., which will be described below, may be arranged in the cell array region R1. The extended region R2 may be disposed around the cell array region R1. The gate electrode 112 to be described below may be stacked in a stepwise manner in the extended region R2.

The memory cell region CELL may include a mold structure MS, a channel structure CS, a source structure SS, and a drain structure DS.

The mold structure MS may include a plurality of gate electrodes 112 and a plurality of mold insulating layers 114, which may be alternately stacked on each other. The gate electrode 112 may correspond to the word line. The mold structure MS may be disposed on a bottom surface of a source plate SP that forms the source structure SS. Each of the plurality of gate electrodes 112 and the plurality of mold insulating layers 114 may be alternately stacked on each other in a first direction perpendicular to the bottom surface of the source plate SP and may extend in a second direction parallel to the bottom surface of the source plate SP. In the cell array region R1, the mold structure MS may include a structure in which the plurality of gate electrodes 112 and the mold insulating layers 114 are alternately stacked on each other.

The plurality of gate electrodes 112 may be stacked in a stepwise manner in the extended region R2. For example, the plurality of gate electrodes 112 may extend to different lengths along the second direction D2. Accordingly, steps may be formed between the plurality of gate electrodes 112.

A plurality of channel structures CS may be formed on the mold structure MS of the cell array region R1. The plurality of channel structures CS may extend in a vertical direction (hereinafter, referred to as the first direction D1) intersecting an upper surface of the mold structure MS and penetrate the mold structure MS. For example, the plurality of channel structures CS may have a pillar shape (e.g., cylindrical shape) extending in the first direction D1. In some example embodiments, the width of the channel structure CS may become narrower as the distance from the upper surface of the mold structure MS increases. Depending on designs, the width of the channel structure CS may become wider as the distance from the upper surface of the mold structure MS increases.

As illustrated in FIG. 4, each of the plurality of channel structures CS may include a channel hole CH_H extending in the first direction D1, and a charge storage structure 124 and a channel layer 122 sequentially stacked on an inner wall of the channel hole CH_H.

In some example embodiments, the diameter of the channel hole CH_H may decrease as the distance from the source plate SP increases. However, various example embodiments are not limited thereto. For example, the diameter of the channel hole CH_H may be substantially the same at all vertical levels.

The channel layer 122 may extend in the first direction D1 and penetrate the mold structure MS. Although it is illustrated that the channel layer 122 has a cup shape, this is merely example. For example, the channel layer 122 may have various shapes such as a cylindrical shape, a square cylindrical shape, a filled pillar shape, etc. For example, the channel layer 122 may include a semiconductor material such as single crystal silicon, polycrystalline silicon, an organic semiconductor material, and a carbon nanostructure, but example embodiments are not limited thereto.

The charge storage structure 124 may be interposed between the channel layer 122 and the mold structure MS. The charge storage structure 124 may be interposed between the channel layer 122 and each of the gate electrodes 112. For example, the charge storage structure 124 may extend along an outer surface of the channel layer 122. For example, the charge storage structure 124 may include at least one of silicon oxide, silicon nitride, silicon oxynitride, and a high-k material having a higher dielectric constant than the silicon oxide. However, example embodiments are not limited thereto. For example, the high-k material may include at least one of aluminum oxide, hafnium oxide, lanthanum oxide, tantalum oxide, titanium oxide, lanthanum hafnium oxide, lanthanum aluminum oxide, dysprosium scandium oxide, and a combination thereof.

In some example embodiments, the channel layer 122 may further extend in the second and third directions D2 and D3 perpendicular to the first direction D1 on the upper surface of the mold structure MS. For example, the channel layer 122 may extend from the outer wall of the channel hole CH_H and extend along the bottom surface of the source plate SP. In this case, the charge storage structure 124 may be disposed on the upper surface of the mold structure MS, and between the channel layer 122 and the upper surface of the mold structure MS. For example, as illustrated in FIG. 4, the charge storage structure 124 and the channel layer 122 may be sequentially disposed on the upper surface of the mold structure MS.

In some example embodiments, the channel structure CS may further include a pad layer 128. Referring to FIG. 5, the pad layer 128 may be positioned at one end of the channel structure CS (e.g., in an upper region of the channel structure CS). The pad layer 128 may be disposed on an inner wall of the channel layer 122. The pad layer 128 may be formed to be connected to the channel layer 122. For example, the pad layer 128 may include polysilicon, metal, etc., which may be doped with impurities, but example embodiments are not limited thereto. Meanwhile, FIG. 5 illustrates that the pad layer 128 overlaps the gate electrode 112 at a top end of the mold structure MS in the horizontal direction (e.g., in the third direction), but it may overlap two or more gate electrodes 112 at a top end of the immersion structure MS in the horizontal direction.

In some example embodiments, the plurality of channel structures CS may be arranged in a zigzag form. For example, as illustrated in FIG. 2, the plurality of channel structures CS may be arranged to cross each other in the second direction D2 and the third direction D3. The plurality of channel structures CS arranged in the zigzag form may further improve the degree of integration of the semiconductor memory device. In some example embodiments, the plurality of channel structures CS may be arranged in a honeycomb form.

In some example embodiments, a dummy channel structure DCH may be formed in the mold structure MS of the extended region R2. The dummy channel structure DCH may be formed in a shape similar to that of the channel structure CS to reduce the stress applied to the mold structure MS in the extended region R2.

In some example embodiments, the charge storage structure 124 may be formed of a multilayer. For example, the charge storage structure 124 may include a tunnel insulating film 124a, a charge storage film 124b, and a blocking insulating film 124c, which may be sequentially stacked on the outer surface of the channel layer 122.

For example, the tunnel insulating film 124a may include the silicon oxide or a high-k material (e.g., aluminum oxide (Al₂O₃), hafnium oxide (HfO₂)) having a higher dielectric constant than the silicon oxide, the charge storage film 124b may include the silicon nitride, and the blocking insulating film 124c may include the silicon oxide or a high-k material (e.g., aluminum oxide (Al₂O₃) or hafnium oxide (HfO₂)) having a higher dielectric constant than the silicon oxide. However, example embodiments are not limited thereto.

In some example embodiments, the channel structure CS may further include a filling pattern 126. The filling pattern 126 may be formed to fill the inside of the channel layer 122. For example, the filling pattern 126 may include an insulating material, for example, silicon oxide, but example embodiments are not limited thereto.

The source structure SS may be disposed on the mold structure MS. The source structure SS may include a source plate SP, a contact pad SC, and a first interlayer insulating film 152.

The source plate SP may extend along the upper surface of the mold structure MS. The source plate SP may be entirely disposed on the upper surface of the mold structure MS. The source plate SP may be in direct or indirect contact with the channel layer 122 of the channel structure CS. As illustrated in FIG. 4, if the channel layer 122 is disposed on the upper surface of the mold structure MS, the source plate SP may be disposed on the channel layer 122 and in direct contact with the channel layer 122. As illustrated in FIG. 5, if the pad layer 128 is disposed on the channel structure CS, the source plate SP may be electrically connected to the channel layer 122 through the pad layer 128, and may also be in contact with a partial region of the channel layer 122.

The source plate SP may be connected to the channel layer 122 to be provided as a common source line of the semiconductor memory device (e.g., the CSL of FIG. 2). For example, a contact pad SC connected to upper portions of the plurality of channel structures CS may be formed in the first interlayer insulating film 152. That is, the channel structure CS may be electrically connected to the common source line through the source plate SP and the contact pad SC.

The first interlayer insulating film 152 may be disposed on the source plate SP. For example, the first interlayer insulating film 152 may include at least one of silicon oxide, silicon oxynitride, and a low-k material having a dielectric constant lower than that of silicon oxide, but example embodiments are not limited thereto.

The source plate SP may include polysilicon or metal doped with impurities. In some example embodiments, the source plate SP may be (p−) polysilicon doped with p-type impurities at a low concentration. However, example embodiments are not limited thereto.

Referring back to FIG. 2, the block separation structure WLC may extend in the second direction D2 to separate or partition the mold structure MS. The mold structure MS may be separated by a plurality of block separation structures WLC to form a plurality of memory cell blocks. For example, two adjacent block separation structures WLC may define one memory cell block therebetween. A plurality of channel structures CS may be disposed in each of the memory cell blocks defined by the block separation structures WLC.

The number of channel structures CS arranged in the zigzag form along the third direction D3 in one memory cell block may vary, without being limited to examples embodiments as illustrated in FIG. 2.

In some example embodiments, the block separation structure WLC may include an insulating material. For example, the insulating material may fill the block separation structure WLC. For example, the insulating material may include at least one of silicon oxide, silicon nitride, and silicon oxynitride, but example embodiments are not limited thereto.

In some example embodiments, although not illustrated, the string separation structure may be formed in the mold structure MS. The string separation structure may extend in the second direction D2 to cut the gate electrode 112. The string separation structure may cut a portion of the gate electrode 112 disposed at a top portion. Each of the memory cell blocks defined by the block separation structure WLC may be divided by the string separation structure to form a plurality of string regions. For example, the string separation structure may define two string regions in one memory cell block.

A cell contact structure 170 may be connected to the gate electrode 112 in the extended region R2. The cell contact structure 170 may extend in the first direction D1 and penetrate the mold structure MS. The cell contact structure 170 may be connected to the pad region of each of the gate electrodes 112.

Each of the gate electrodes 112 may correspond to the ground select line GSL, a plurality of word lines WL, and the string select line SSL of FIG. 2. In addition, in some example embodiments, the gate electrode adjacent to the ground select line GSL, or the gate electrode adjacent to the string select line SSL may be a dummy semiconductor layer.

For example, the mold insulating layer 114 may include an insulating material, for example, at least one of silicon oxide, silicon nitride, and silicon oxynitride, but example embodiments are not limited thereto. For example, the mold insulating layer 114 may include silicon oxide.

The drain structure DS may be disposed under the mold structure MS. The drain structure DS may include the bit line BL, a bit line contact BLC, a bit line contact pad BLP, and a second interlayer insulating film 154.

The bit line BL may be formed under the mold structure MS and the second interlayer insulating film 154. The bit line BL may extend in the third direction D3 and intersect the block separation structure WLC. In addition, the bit line BL may extend in the third direction D3 and be connected to the plurality of channel structures CS arranged along the third direction D3. For example, the bit line contact pad BLP and the bit line contact BLC connected to an upper portion of each of the channel structures CS may be formed in the second interlayer insulating film 154. The bit line BL may be electrically connected to the channel structures CS via the bit line contact pad BLP and the bit line contact BLC.

The peripheral circuit region PERI may include a peripheral circuit substrate 200, a plurality of circuit elements PT formed on the peripheral circuit substrate 200, a metal layer 260 connected to each of the plurality of circuit elements PT, and an interlayer insulating layer 240 formed on the peripheral circuit substrate 200 to bury the plurality of circuit elements PT and the metal layer 260.

The peripheral circuit substrate 200 may be disposed under the drain structure DS. For example, an upper surface of the peripheral circuit substrate 200 may face a lower surface of the drain structure DS. For example, the peripheral circuit substrate 200 may include a semiconductor substrate such as a silicon substrate, a germanium substrate, or a silicon-germanium substrate. However, example embodiments are not limited thereto. Alternatively, the peripheral circuit substrate 200 may also include a silicon-on-insulator (SOI) substrate or a germanium-on-insulator (GOI) substrate, etc.

The circuit elements PT may be formed on the peripheral circuit substrate 200. The circuit elements PT may form a peripheral circuit that controls an operation of the semiconductor memory device. For example, the circuit elements PT may include a control logic, a row decoder, a page buffer, etc.

For example, the circuit elements PT may include a transistor, but example embodiments are not limited thereto. For example, the circuit elements PT may include not only various active elements such as transistors, but also various passive elements such as capacitors, registers, and inductors.

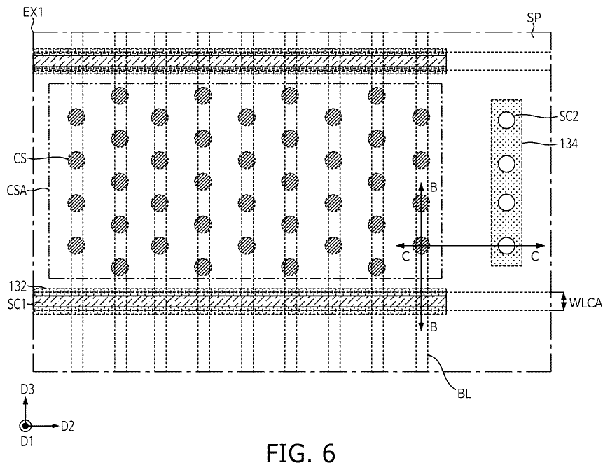

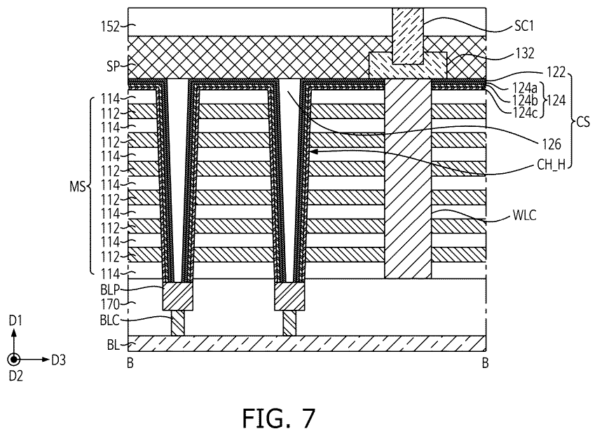

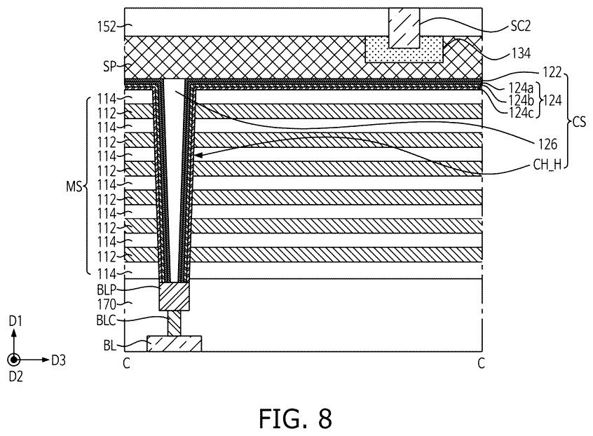

FIGS. 6 to 8 are diagrams provided to explain a semiconductor memory device. FIG. 6 is a plan view of a source plate with respect to the region EX1 of FIG. 2. FIG. 7 is a cross-sectional view taken along the cross section B-B of FIG. 6. FIG. 8 is a cross-sectional view taken along the cross section C-C of FIG. 6. For convenience of description, the elements or operations overlapping those already described above with reference to FIGS. 1 to 5 will be briefly described or will not be described.

In some example embodiments, the source plate SP may include a first conductivity type impurity region 132 and a second conductivity type impurity region 134. The first conductivity type impurity region 132 may be a region doped with n-type impurities. In addition, the second conductivity type impurity region 134 may be a region doped with p-type impurities. The impurity concentration of the second conductivity type impurity region 134 may be higher than the impurity concentration of a semiconductor material of the source plate SP.

In some example embodiments, the first conductivity type impurity region 132 of the source plate SP may be in contact with the channel layer 122. For example, as illustrated in FIG. 7, at least a portion of one side surface of the first conductivity type impurity region 132 may be in direct contact with the channel layer 122.

The source plate SP may be disposed on the upper surface of the mold structure MS. When viewed from the upper surface of the mold structure MS, the upper surface of the mold structure MS may include a channel array region CSA and a block separation region WLCA. The channel array region CSA may represent a region that includes the plurality of channel structures CS disposed along the second and third directions D2 and D3, the second and third directions D2 and D3 being perpendicular to the first direction D1. In addition, the block separation region WLCA may include a block separation structure WLC disposed to extend in the second direction D2 to separate the channel array region CSA into a plurality of blocks. A plurality of block separation structures WLC may be arranged to be spaced apart from the channel array region CSA in the third direction D3.

In some example embodiments, as illustrated in FIG. 6, the first conductivity type impurity region 132 may extend in the second direction D2 on the block separation region WLCA. As illustrated in FIG. 7, the first conductivity type impurity region 132 may overlap the block separation structure WLC in the first direction D1.

In some example embodiments, the second conductivity type impurity region 134 may be spaced apart from the channel array region CSA in the second direction D2, and may extend in the third direction D3. For example, as illustrated in FIGS. 6 and 8, the second conductivity type impurity region 134 may not overlap the channel array region CSA and the block separation region WLCA along the first direction D1. That is, the second conductivity type impurity region 134 may be independently provided, without overlapping the channel structure CS and the block separation structure WLC along the first direction D1.

In some example embodiments, a first contact pad SC1 may be formed on the first conductivity type impurity region 132. By a desired (and/or alternatively predetermined) program voltage applied through the first contact pad SC1, the channel structure CS may receive a charge (electron) through the source plate SP and thus perform a program (or read) operation.

In some example embodiments, a second contact pad SC2 may be formed on an upper surface of the second conductivity type impurity region 134. By a desired (and/or alternatively predetermined) erase voltage applied through the second contact pad SC2, the channel structure CS may receive a current through the source plate SP (i.e., due to electron migration) and thus perform an erase operation.

Specifically, in the program operation, a program voltage may be applied between the gate electrode 112 and the channel layer 122. For example, a relatively high DC voltage may be applied to the gate electrode 112, and as a result, charge (electrons) may be trapped in the charge storage film 124b. In the erase operation, a desired (and/or alternatively predetermined) erase voltage may be applied through the second contact pad SC2. As a result, the charges trapped in the charge storage film 124b may exit to the channel layer 122.

As such, according to various example embodiments, the erase voltage may be applied to the impurity region (e.g., the second conductivity type impurity region 134) formed in the source plate SP disposed above the channel hole CH_H in the erase operation, so that a sufficient amount of erase voltage may be applied to the channel layer of the channel structure without requiring a separate structure (e.g., GIDL WL) for the erase operation. Furthermore, the first conductivity type impurity region for program operation and the second conductivity type impurity region for erase operation are separately formed on the source plate (SP), thereby reducing, or minimizing interference between a moving path of electric charges in the program operation and a moving path of electric charges in the erase operation, and providing a semiconductor memory device with improved reliability and/or stability.

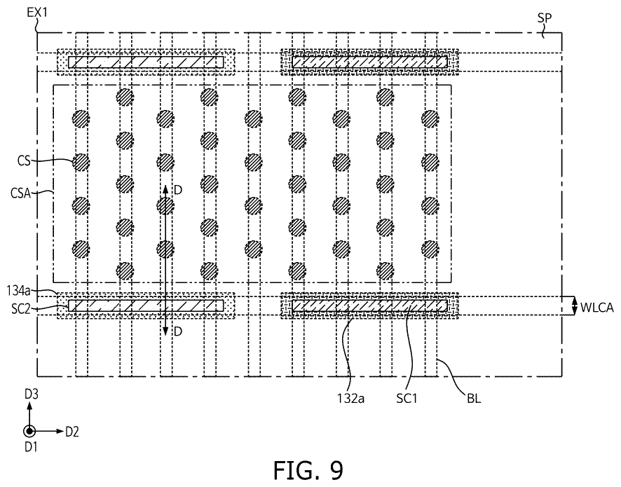

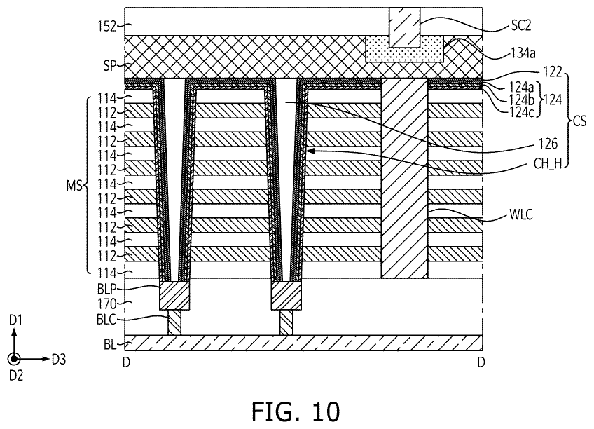

FIGS. 9 and 10 are diagrams provided to explain a semiconductor memory device according to various example embodiments. FIG. 9 is a plan view of a source plate according to various example embodiments with respect to the region EX1 of FIG. 2. FIG. 10 is a cross-sectional view taken along the cross section D-D of FIG. 9. For convenience of description, the elements or operations overlapping those already described above with reference to FIGS. 1 to 8 will be briefly described or will not be described.

In some example embodiments, a first conductivity type impurity region 132a and a second conductivity type impurity region 134a may be alternately disposed along the second direction D2 on the block separation structure WLC of the block separation region WLCA. For example, as illustrated in FIG. 9, the first conductivity type impurity region 132a may be disposed and extend in the second direction D2 in the block separation region WLCA. The second conductivity type impurity region 134a may be disposed and spaced apart from the adjacent first conductivity type impurity region 132a in the second direction D2. The second conductivity type impurity region 134a may extend in the second direction D2. Referring to FIG. 10, the second conductivity type impurity region 134a may be spaced apart from each other on the block separation structure WLC. In this case, the second conductivity type impurity region 134a may overlap the block separation structure WLC in the first direction D1.

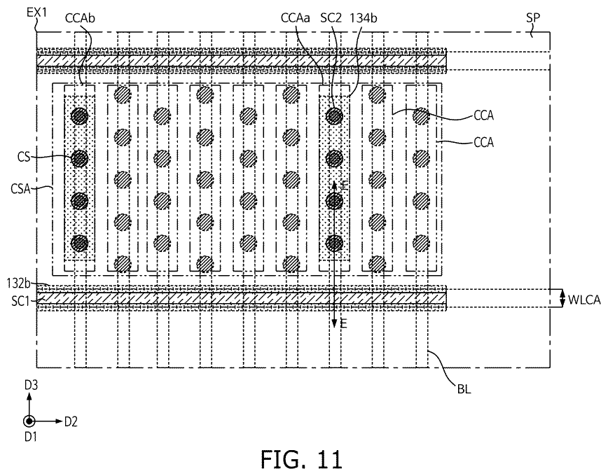

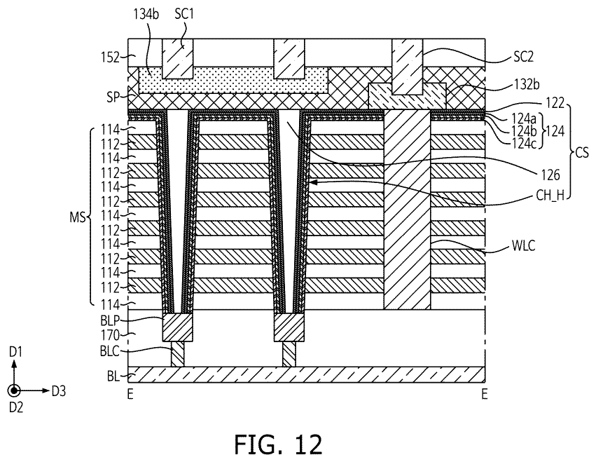

FIGS. 11 and 12 are diagrams illustrating a semiconductor memory device according to various example embodiments. FIG. 11 is a plan view of a source plate according various example embodiments with respect to the region EX1 of FIG. 2. FIG. 12 is a cross-sectional view taken along the cross section E-E of FIG. 11. For convenience of description, the elements or operations overlapping those already described above with reference to FIGS. 1 to 10 will be briefly described or will not be described.

In some example embodiments, the first conductivity type impurity region 132b may be disposed on the block separation structure WLC of the block separation region WLCA and extend in the second direction D2. In addition, the second conductivity type impurity region 134b may be disposed in a partial region of the source plate SP corresponding to the channel array region CSA.

The channel array region CSA may include a plurality of channel column regions CCA in which several channel structures CS are disposed along the second direction D2. In this case, as illustrated in FIG. 11, the second conductivity type impurity region 134b may be disposed in at least one (CCAa, CCAb) of the plurality of channel column regions (CCA).

Referring to FIG. 12, the second conductivity type impurity region 134b may be spaced apart from each other on the channel structure CS. The distance at which the second conductivity type impurity region 134b is spaced apart from the channel structure CS may be a desired (and/or alternatively predetermined) distance that may not cause interference with the moving path of the charges according to the program operation through the first conductivity type impurity region 132b. The second conductivity type impurity region 134b may overlap the channel structure CA in the first direction D1.

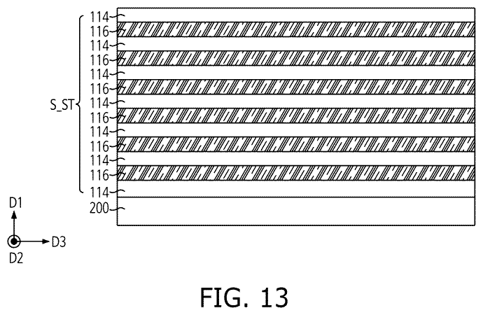

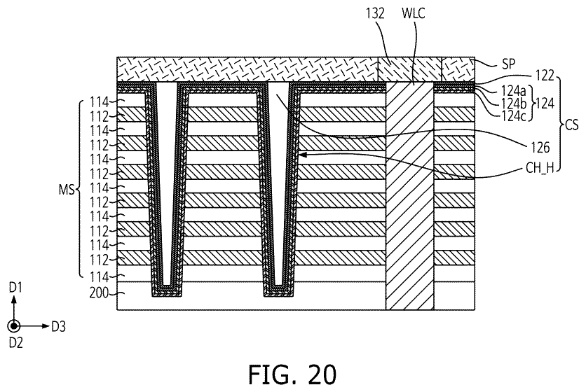

FIGS. 13 to 24 are diagrams provided to explain a method for manufacturing a semiconductor device according to various example embodiments, which illustrate intermediate stages of manufacturing. FIGS. 13 through 24 will be described below, mainly focusing on a method for manufacturing the cell array region R1 of the semiconductor device.

Referring to FIG. 13, a method for manufacturing a semiconductor memory device according to some example embodiments may include forming the stack structure S_ST on the substrate 200.

The substrate 200 may be a silicon substrate, or may include other materials, such as silicon germanium (SiGe), silicon germanium on insulator (SGOI), indium antimony, lead tellurium compound, indium arsenic, indium phosphide, gallium arsenic, or gallium antimony, but example embodiments are not limited thereto. Although not illustrated, an etch stop film may be formed on the substrate 200. The etch stop film may include a material having etch selectivity with respect to the substrate 200. For example, the etch stop film may include a silicon nitride film, but example embodiments are not limited thereto.

The stack structure S_ST may be formed on a substrate 100. The stack structure S_ST may include the mold insulating layer 114 and a sacrificial layer 116 alternately stacked on each another. The sacrificial layer 116 may include a material having etch selectivity with respect to the mold insulating layer 114. For example, the mold insulating layer 114 may include a silicon oxide film. The sacrificial layer 116 may include a silicon nitride film. However, example embodiments are not limited thereto. In various example embodiments, the mold insulating layer 114 may be an insulating film, and the sacrificial layer 116 may be a conductive film.

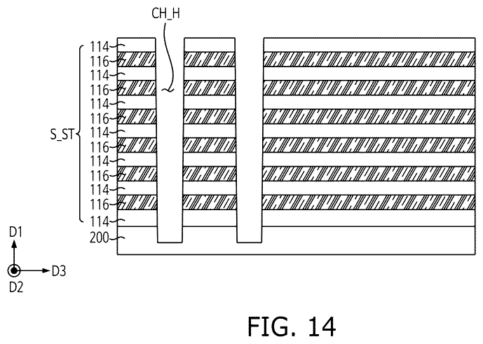

Referring to FIG. 14, a channel hole CH_H penetrating the mold insulating layer 114 and the sacrificial layer 116 may be formed. The channel hole CH-H may be formed such that a portion of the upper surface of the substrate 200 is etched to extend into the substrate 200.

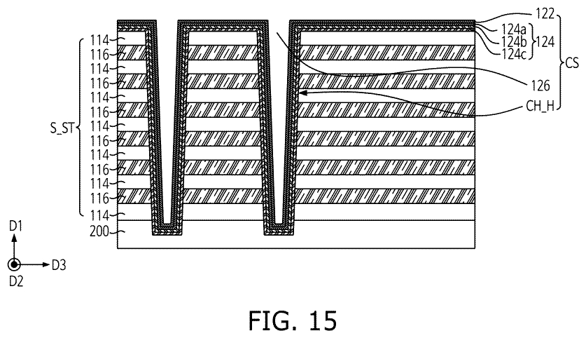

Referring to FIG. 15, the charge storage structure 124, the channel layer 122, and the filling pattern 126 may be formed in order in the channel hole CH_H. The process of forming the charge storage structure 124 may be performed in the order of forming the blocking insulating film 124c, forming the charge storage film 124b on the blocking insulating film 124c, and forming the tunnel insulating film 124a on the charge storage film 124b. The channel layer 122 and the charge storage structure 124 may extend on the upper surface of the stack structure S_ST.

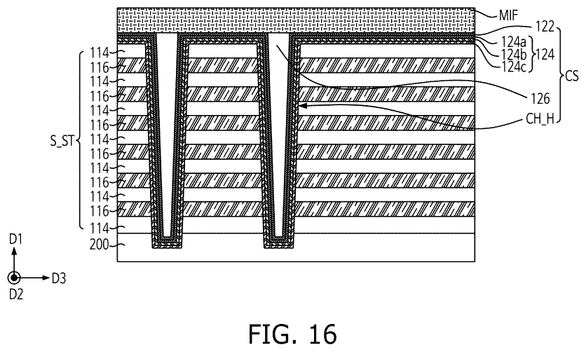

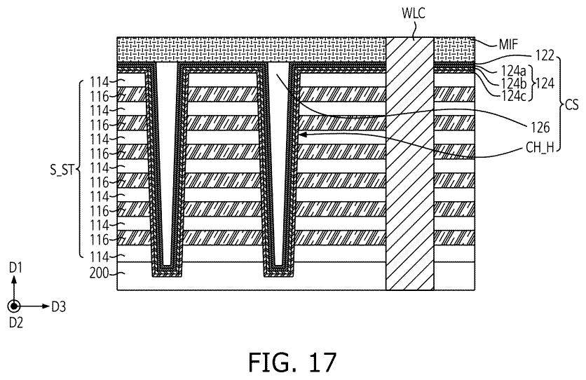

Referring to FIGS. 16 and 17, the intermediate insulating film MIF may be formed on the channel layer 122, and the block separation structure WLC may be formed, penetrating the intermediate insulating film MIF and the stack structure S_ST. Although not illustrated, an etch stop film may be formed between the substrate 200 and the stack structure S_ST, and in this case, the block separation structure WLC may be etched up to the position of the etch stop film.

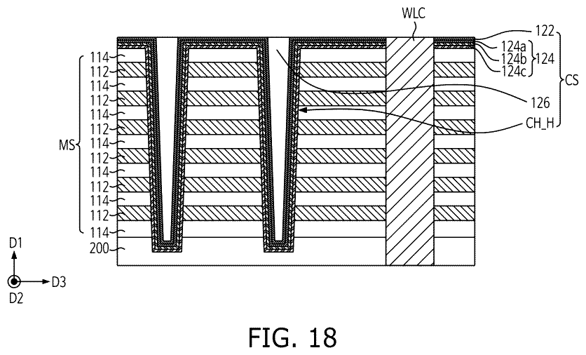

Referring to FIG. 18, the sacrificial layer 116 may be selectively removed through the block separation structure WLC. In this case, the mold insulating layer 114 may remain. The gate electrode 112 may be formed in the empty space generated as the sacrificial layer 116 is removed. As a result, the mold structure MS, defined by the gate electrode 112 and the mold insulating layer 114, may be formed. The intermediate insulating film MIF may be removed.

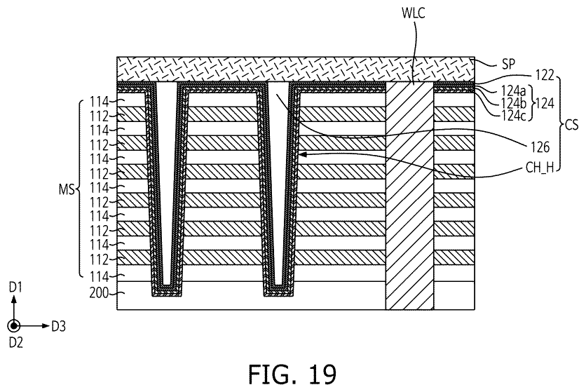

Referring to FIGS. 19 to 22, the source structure SS may be formed on the mold structure MS. For example, the source structure SS may be formed on the upper (or first) surface of the mold structure MS. First, the source plate SP may be formed on the mold structure MS. The source plate SP may include p-type (p−) polysilicon doped at a low concentration. For example, the impurity concentration of the source plate SP may be lower than the impurity concentration (p+) of the second conductivity type impurity region.

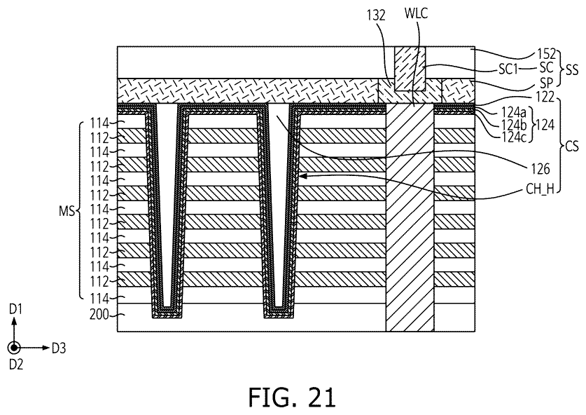

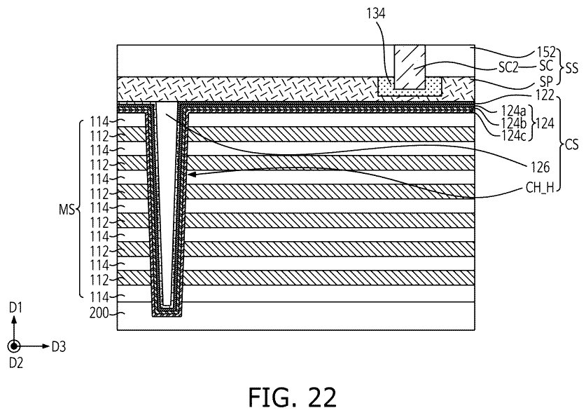

The first conductivity type impurity region 132 and the second conductivity type impurity region 134 may be formed in a partial region of the source plate SP. The first conductivity type impurity region 132 and the second conductivity type impurity region 134 may be formed in a desired (and/or alternatively predetermined) region of the source plate SP. For example, as illustrated in FIG. 21, the first conductivity type impurity region 132 may be formed on the block separation structure (WLC), and as illustrated in FIG. 22, the second conductivity type impurity region 134 may be formed in a region that does not overlap the channel structure (CS) and the block separation structure (WLC) in the first direction D1. However, example embodiments are not limited thereto, and since various aspects of the positions of the first conductivity type impurity region 132 and the second conductivity type impurity region 134 have already been described with reference to FIGS. 6 to 12, repeated descriptions thereof will be omitted. After the first conductivity type impurity region 132 and the second conductivity type impurity region 134 are formed in a partial region of the source plate SP, the first interlayer insulating film 152 may be formed on the source plate SP. The first contact pad SC1 may be formed in the first conductivity type impurity region 132 and the first interlayer insulating film 152, and the second contact pad SC2 may be formed in the second conductivity type impurity region 134 and the first interlayer insulating film 152.

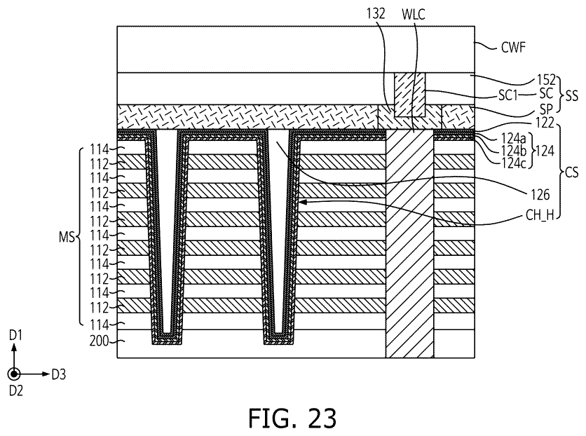

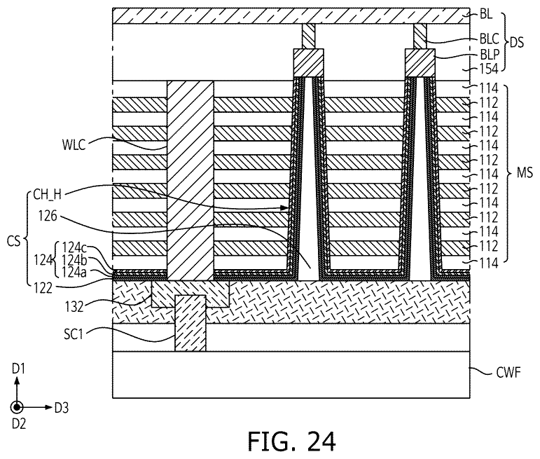

Referring to FIGS. 23 and 24, the drain structure DS may be formed on the lower (or second) surface of the mold structure MS. First, a carrier wafer CWF may be attached onto the source structure SS. The source structure SS and the mold structure MS may be inverted so that the carrier wafer CWF at the top is turned to be at the bottom. The second interlayer insulating film 154 may be formed on the second surface of the mold structure MS. The bit line contact pad BLP and the bit line contact BLC may be formed. The bit line contact pad BLP and the bit line contact BLC may partially penetrate the second interlayer insulating film 154 and the channel structure CS to be connected to the channel layer 122. The bit line contact pad BLP may be omitted. In addition, the bit line BL may be formed on the second interlayer insulating film 154 and the bit line contact BLC.

As a result, the semiconductor memory device as described above with reference to FIGS. 1 to 12 may be provided.

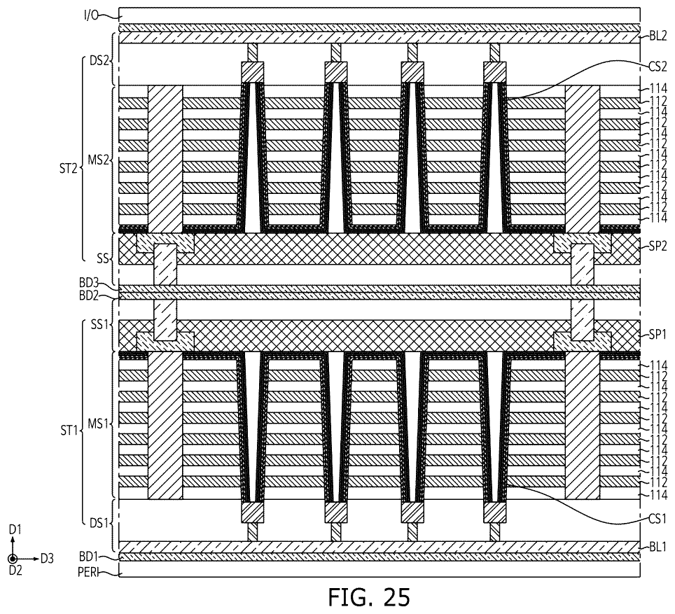

FIG. 25 is a diagram provided to explain a semiconductor memory device according to various example embodiments. A first cell structure ST1 and a second cell structure ST2 of FIG. 25 are semiconductor memory devices as the ones described above with reference to FIGS. 1 to 12, and they may be semiconductor memory devices manufactured by a method that is the same as or similar to the manufacturing method described above with reference to FIGS. 13 to 24.

Referring to FIG. 25, in some example embodiments, the semiconductor memory device may include an input and output interface I/O, a peripheral circuit structure (PERI), the first cell structure ST1, and the second cell structure ST2. The semiconductor memory device may be electrically connected to a controller that controls and/or manages the semiconductor memory device through the input and output interface I/O.

The peripheral circuit structure PERI may include a peripheral circuit substrate (e.g., the peripheral circuit substrate of FIG. 3), a plurality of circuit elements (e.g., a plurality of circuit elements PT of FIG. 3) formed on the peripheral circuit substrate, a metal layer connected to each of the plurality of circuit elements (e.g., 260 of FIG. 3), an interlayer insulating layer (e.g., 240 of FIG. 3) formed on the peripheral circuit substrate to bury a plurality of circuit elements and a metal layer, and a lower bonding metal (e.g., BD0 of FIG. 3) formed on the interlayer insulating layer.

The first cell structure ST1 may include a source structure SS1 including a first source plate SP1 including a semiconductor material, a first mold structure MS1 including the plurality of gate electrodes 112 and the plurality of mold insulating layers 114 disposed on a bottom surface of the first source plate SP1 and alternately stacked on each other, a plurality of first channel structures CS1 penetrating the first mold structure MS1 in the first direction D1, a first bit line BL1 disposed under the plurality of first channel structures CS1, and a first bonding metal BD1 disposed under the first bit line BL1. The first bonding metal BD1 may be bonded to a lower bonding metal BD0 above the peripheral circuit structure PERI. The first source plate SP1 may include a first conductivity type impurity region (e.g., a region doped with n-type impurities) and a second conductivity type impurity region (e.g., a region doped with p-type impurities). Each of the plurality of gate electrodes 112 and the plurality of mold insulating layers 114 may be spaced apart in the first direction D1 perpendicular to the bottom surface of the first source plate SP1, and may extend in the second direction D2 parallel to the bottom surface of the first source plate SP1. Each of the plurality of first channel structures CS1 may include a channel hole extending in the first direction D1, and a charge storage structure and a channel layer stacked in order on the inner wall of the channel hole. In addition, the first cell structure ST1 may include a second bonding metal BD2 on the source structure SS1.

The first cell structure ST1 may be disposed on the peripheral circuit structure PERI. The peripheral circuit structure PERI and the first cell structure ST1 may be connected to each other by the lower bonding metal BD0 and the first bonding metal BD1. Each of the lower bonding metal BD0 and the first bonding metal BD1 may be formed of aluminum, copper, tungsten, etc., but example embodiments are not limited thereto.

In some example embodiments, the semiconductor memory device may further include the second cell structure ST2 on the first cell structure ST1. The second cell structure ST2 may include a source structure SS2 including a second source plate SP2 including a semiconductor material, a third bonding metal BD3 disposed under the second source plate SP2, a second mold structure MS2 including the plurality of gate electrodes 112 and the plurality of mold insulating layers 114 arranged to be alternately stacked on each other on the second source plate SP2, a plurality of second channel structures CS2 penetrating the second mold structure MS2 in the first direction D1, and a second bit line BL2 disposed on the plurality of second channel structures CS2. The second source plate SP2 may include a first conductivity type impurity region (e.g., a region doped with n-type impurities) and a second conductivity type impurity region (e.g., a region doped with p-type impurities). Each of the plurality of gate electrodes 112 and the plurality of mold insulating layers 114 may be spaced apart in the first direction D1 perpendicular to the bottom surface of the second source plate SP2, and may extend in the second direction D2 parallel to the bottom surface of the second source plate SP2. Each of the plurality of second channel structures CS2 may include a channel hole extending in the first direction D1, and a charge storage structure and a channel layer stacked in order on the inner wall of the channel hole.

The second cell structure ST2 may be disposed on the first cell structure ST1 with the top and bottom thereof inverted compared to the first cell structure ST1. The first cell structure ST1 and the second cell structure ST2 may be bonded by the second bonding metal BD2 and the third bonding metal BD3. The second bonding metal BD2 and the third bonding metal BD3 may be formed of aluminum, copper, tungsten, etc., but example embodiments not limited thereto.

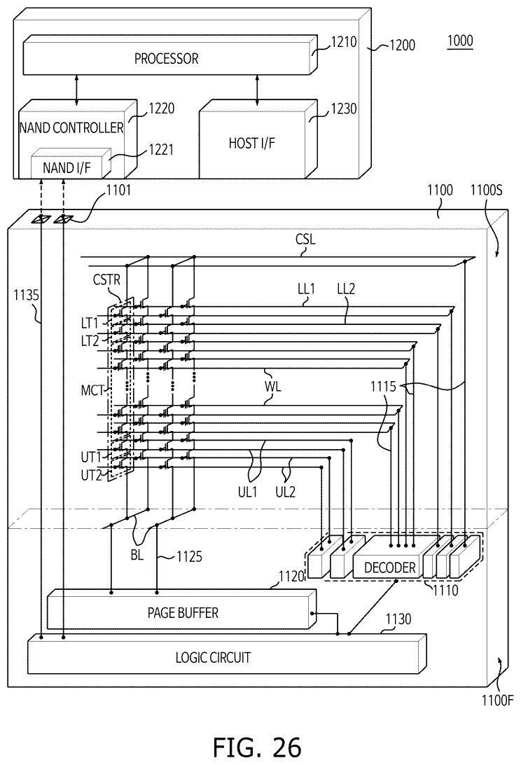

FIG. 26 is a conceptual diagram schematically illustrating an electronic system 1000 including a semiconductor device 1100.

Referring to FIG. 26, the electronic system 1000 may include the semiconductor device 1100 and a controller 1200 electrically connected to the semiconductor device 1100. The electronic system 1000 may be a storage device including one or a plurality of semiconductor devices 1100 or an electronic device including a storage device. For example, the electronic system 1000 may be a solid state drive device (SSD), a universal serial bus (USB), a computing system, a medical device, or a communication device including one or a plurality of semiconductor devices 1100.

For example, the semiconductor device 1100 may be a non-volatile memory device, for example, the NAND flash memory device described above with reference to FIGS. 1 to 25. The semiconductor device 1100 may include a first structure 1100F and a second structure 1100S on the first structure 1100F. In some example embodiments, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL and upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be modified according to various example embodiments.

In some example embodiments, the upper transistors UT1 and UT2 may include a string select transistor, and the lower transistors LT1 and LT2 may include a ground select transistor. The gate lower lines LL1 and LL2 each may be gate electrodes of the lower transistors LT1 and LT2. The word lines WL may be gate electrodes of the memory cell transistors MCT, and the gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection lines 1115 extending from within the first structure 1100F and to the second structure 1100S. The bit lines BL may be electrically connected to the page buffer 1120 through second connection wires 1125 extending from within the first structure 1100F and to the second structure 1100S.

In the first structure 1100F, the decoder circuit 1110 and the page buffer 1120 may perform a control operation on at least one memory cell transistor selected from among the plurality of memory cell transistors MCT. The decoder circuit 1110 and the page buffer 1120 may be controlled by the logic circuit 1130. The semiconductor device 1100 may communicate with the controller 1200 through an input and output pad 1101 electrically connected to the logic circuit 1130. The input and output pad 1101 may be electrically connected to the logic circuit 1130 through an input and output connection wiring 1135 extending from within the first structure 1100F and to the second structure 1100S.

The controller 1200 may include a processor 1210, a NAND controller 1220, and a host interface 1230. According to some example embodiments, the electronic system 1000 may include a plurality of semiconductor devices 1100, and in this case, the controller 1200 may control the plurality of semiconductor devices 1100.

The processor 1210 may control the overall operation of the electronic system 1000 including the controller 1200. The processor 1210 may operate according to desired (and/or alternatively predetermined) firmware, and may control the NAND controller 1220 to access the semiconductor device 1100. The NAND controller 1220 may include a NAND interface 1221 that processes communication with the semiconductor device 1100. A control command for controlling the semiconductor device 1100, data to be written in the memory cell transistors MCT of the semiconductor device 1100, data to be read from the memory cell transistors MCT of the semiconductor device 1100, etc., and may be transmitted through the NAND interface 1221. The host interface 1230 may provide a function of communication between the electronic system 1000 and an external host. Upon receiving a control command from the external host through the host interface 1230, the processor 1210 may control the semiconductor device 1100 in response to the control command.

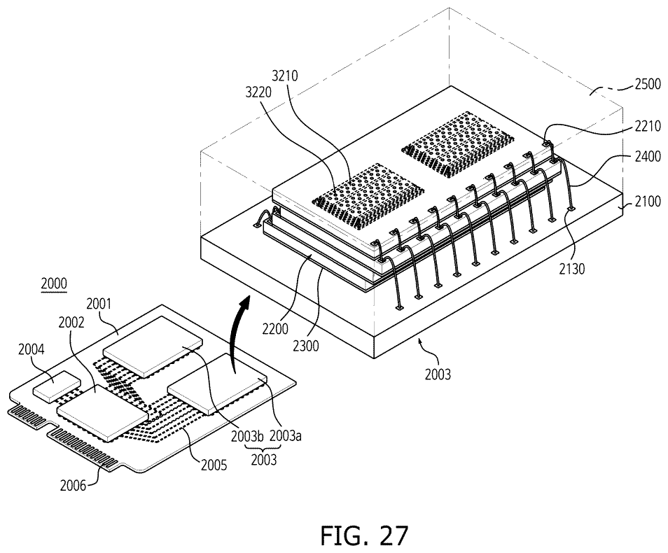

FIG. 27 is a perspective view schematically illustrating an electronic system 2000 including a 3D semiconductor memory device according various example embodiments.

Referring to FIG. 27, the electronic system 2000 according to various example embodiments may include a main substrate 2001, a controller 2002 mounted on the main substrate 2001, one or more semiconductor packages 2003, and a DRAM 2004. The semiconductor package 2003 and the DRAM 2004 may be connected to the controller 2002 by wiring patterns 2005 provided to the main substrate 2001.

The main substrate 2001 may include a connector 2006 including a plurality of pins coupled to the external host. The number and arrangement of the plurality of pins in the connector 2006 may vary according to a communication interface between the electronic system 2000 and the external host. For example, the electronic system 2000 may communicate with the external host according to any one of interfaces such as Universal Serial Bus (USB), Peripheral Component Interconnect Express (PCI-Express), Serial Advanced Technology Attachment (SATA), M-Phy for Universal Flash Storage (UFS), Compute Express Link (CXL), Universal Chiplet Interconnect Express (UCIe), etc. For example, the electronic system 2000 may operate by the power supplied from the external host through the connector 2006. The electronic system 2000 may further include a Power Management Integrated Circuit (PMIC) that distributes the power supplied from the external host to the controller 2002 and the semiconductor package 2003.

The controller 2002 may record data in the semiconductor package 2003 or read data from the semiconductor package 2003, and may improve the operation speed of the electronic system 2000.

The DRAM 2004 may be a buffer memory to alleviate the speed difference between the external host and the semiconductor package 2003 that is a data storage space. The DRAM 2004 included in the electronic system 2000 may also operate as a kind of cache memory, and may also provide a space for temporarily storing data in a control operation for the semiconductor package 2003. If the electronic system 2000 includes the DRAM 2004, in addition to the NAND controller for controlling the semiconductor package 2003, the controller 2002 may further include a DRAM controller for controlling the DRAM 2004.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on a lower surface of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each of the semiconductor chips 2200 may include input and output pads 2210. Each of the semiconductor chips 2200 may include gate stack structures 3210 and vertical channel structures 3220. Each of the semiconductor chips 2200 may include the 3D semiconductor memory device described above.

For example, the connection structure 2400 may be a bonding wire electrically connecting the input and output pads 2210 and the package upper pads 2130. In each of the first and second semiconductor packages 2003a and 2003b, the semiconductor chips 2200 may be electrically connected to each other with the bonding wire method, and may be electrically connected to the package upper pads 2130 of the package substrate 2100. According to some example embodiments, in each of the first and second semiconductor packages 2003a and 2003b, the semiconductor chips 2200 may be electrically connected to each other by through-electrodes (Through Silicon Via, TSV), instead of the bonding wire type connection structure 2400.

For example, the controller 2002 and the semiconductor chips 2200 may be included in one package. For example, the controller 2002 and the semiconductor chips 2200 may be mounted on a separate interposer substrate different from the main substrate 2001, and the controller 2002 and the semiconductor chips 2200 may be connected to each other by wiring provided on the interposer substrate.

Any of the elements disclosed above may include and/or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Although various example embodiments have been described above by way of certain limited example embodiments and drawings, the example embodiments are not limited thereto, and it goes without saying that various changes and modifications can be made within the equivalent scope of the technical idea of the present disclosure and the claims to be described below by those of ordinary skill in the art.

What is claimed is:

1. A semiconductor memory device comprising:
a source plate including a semiconductor material;
a mold structure on a bottom surface of the source plate;
the mold structure including a plurality of gate electrodes and a plurality of mold insulating layers alternately stacked on each other in a first direction, the first direction being perpendicular to the bottom surface of the source plate;
each of the plurality of gate electrodes and the plurality of mold insulating layers extend in a second direction, the second direction being parallel to the bottom surface of the source plate;
a plurality of channel structures penetrating the mold structure in the first direction; and
each of the plurality of channel structures including
a channel hole extending in the first direction,
a charge storage structure on an inner wall of the channel hole, and
a channel layer on the charge storage structure,
wherein the source plate includes a first conductivity type impurity region and a second conductivity type impurity region, and
the channel layer extends along the bottom surface of the source plate in the second direction.

2. The semiconductor memory device of claim 1, wherein a diameter of the channel hole decreases as a distance from the source plate increases.

3. The semiconductor memory device of claim 1, wherein the channel layer is in contact with the source plate.

4. The semiconductor memory device of claim 1, wherein the first conductivity type impurity region is in contact with the channel layer.

5. The semiconductor memory device of claim 1, wherein the charge storage structure of each of the channel structures is between the mold structure and the channel layer.

6. The semiconductor memory device of claim 1, wherein
the mold structure further includes a block separation structure extending in the first direction, and
the first conductivity type impurity region is on the block separation structure.

7. The semiconductor memory device of claim 1, further comprising:
a channel array region including the plurality of channel structures arranged along the second and third directions, the second and third directions being perpendicular to the first direction and the second and third directions being perpendicular to each other; and
a block separation region including a block separation structure extending in the second direction and separating the channel array region into a plurality of blocks,
wherein the block separation region includes a plurality of block separation structures spaced apart in the third direction.

8. The semiconductor memory device of claim 7, wherein
the first conductivity type impurity region extends on the block separation structure in the second direction, and
a first contact pad is on the first conductivity type impurity region.

9. The semiconductor memory device of claim 7, wherein the second conductivity type impurity region does not overlap the channel array region and the block separation region along the first direction.

10. The semiconductor memory device of claim 9, wherein
the second conductivity type impurity region is spaced apart from the channel array region in the second direction and extend in the third direction, and
a second contact pad is an upper surface of the second conductivity type impurity region.

11. The semiconductor memory device of claim 7, wherein
the first conductivity type impurity region is on the block separation structure and extends in the second direction, and
the second conductivity type impurity region is in a region of the source plate adjacent to the channel array region.

12. The semiconductor memory device of claim 11, wherein
the channel array region includes a plurality of channel column regions,
the channel column regions including a plurality of channel structures extending along the second direction, and
the second conductivity type impurity region is in one or more of channel column regions.

13. The semiconductor memory device of claim 7, wherein
the first conductivity type impurity region and the second conductivity type impurity region are alternately arranged on each block separation structure of the block separation region along the second direction.

14. The semiconductor memory device of claim 1, wherein
the semiconductor material of the source plate comprises polysilicon doped with a p-type impurity,
the first conductivity type impurity region is a region doped with n-type impurity,
the second conductivity type impurity region is doped with p-type impurity, and
an impurity concentration of the second conductivity type impurity region is higher than an impurity concentration of the semiconductor material of the source plate.

15. A semiconductor memory device comprising:
a peripheral circuit structure;
a first cell structure on the peripheral circuit structure;
the peripheral circuit structure including
a peripheral circuit substrate,
a plurality of circuit elements on the peripheral circuit substrate,
a metal layer connected to each of the plurality of circuit elements, and
an interlayer insulating layer on the peripheral circuit substrate to bury the plurality of circuit elements and the metal layer;
the first cell structure including a first source plate;
the first source plate including
a semiconductor material,
a first conductivity type impurity region, and
a second conductivity type impurity region;
a first mold structure including a plurality of gate electrodes and a plurality of mold insulating layers on a bottom surface of the first source plate and alternately stacked on each other in a first direction perpendicular to the bottom surface of the first source plate;
each of the plurality of gate electrodes and the plurality of mold insulating layers extending in a second direction parallel to the bottom surface;
a plurality of first channel structures penetrating the first mold structure in the first direction;
each of the plurality of first channel structures including
a channel hole extending in the first direction,
a charge storage structure on an inner wall of the channel hole, and
a channel layer on the charge storage structure;
a first bit line under the plurality of first channel structures; and
the channel layer extending along the bottom surface of the first source plate in the second direction.

16. The semiconductor memory device of claim 15, comprising:
a channel array region including a plurality of channel structures arranged along the second and third directions, the second and third directions being perpendicular to the first direction, and the second and third directions being perpendicular to each other; and
a block separation region including a block separation structure extending in the second direction and separating the channel array region into a plurality of blocks,
wherein the block separation region includes a plurality of block separation structures spaced apart in the third direction.

17. The semiconductor memory device of claim 16, wherein
the first conductivity type impurity region is on the block separation region and extends in the second direction, and
the second conductivity type impurity region does not overlap the channel array region and the block separation region along the first direction.

18. The semiconductor memory device of claim 16, wherein
the first conductivity type impurity region is on the block separation region and extends in the second direction, and
the second conductivity type impurity region is in a region of the first source plate adjacent to the channel array region.

19. The semiconductor memory device of claim 16, further comprising:
a second cell structure on the first cell structure;
the second cell structure including a second source plate;
the second source plate including a semiconductor material;
the second source plate including a first conductivity type impurity region and a second conductivity type impurity region;
a third bonding metal under the second source plate;
a second mold structure above the second source plate;
the second mold structure including a plurality of gate electrodes and a plurality of mold insulating layers alternately stacked on each other in a first direction perpendicular to the bottom surface of the first source plate;
a plurality of second channel structures penetrating the second mold structure in the first direction;
each of the plurality of second channel structures including a channel hole extending in the first direction;
a charge storage structure on the inner wall of the channel hole;
a channel layer on the charge storage structure; and
a second bit line on the plurality of second channel structures.

20. A semiconductor memory device comprising:
a source plate including a semiconductor material;
the source plate including a first conductivity type impurity region and a second conductivity type impurity region;
a mold structure on a bottom surface of the source plate;
the mold structure including a plurality of gate electrodes and a plurality of mold insulating layers alternately stacked on each other in a first direction perpendicular to the bottom surface of the source plate;
each of the plurality of gate electrodes and the plurality of mold insulating layers extending in a direction parallel to the bottom surface of the source plate;
a plurality of channel structures penetrating the mold structure in the first direction;
each of the plurality of channel structures including a channel hole extending in the first direction;
a charge storage structure on an inner wall of the channel hole;
a channel layer on the charge storage structure, and the channel layer being in contact with the source plate;
a block separation structure penetrating the mold structure in the first direction;
the first conductivity type impurity region on the block separation structure;
a bit line under the plurality of channel structures;
the channel layer extending along the bottom surface of the source plate in a second direction, the second direction being perpendicular from the first direction; and
the channel layer including
a channel array region including the plurality of channel structures arranged along second and third directions perpendicular to the first direction, the second and third directions being perpendicular to each other, and
a block separation region including the block separation structure extending in the second direction and separating the channel array region into a plurality of blocks,
wherein the block separation structure includes a plurality of block separation structures spaced apart in the third direction.
